(19) United States
(12) Patent Application Publication
(10) Pub. No.: US 2007/0161180 A1
(43) Pub. Date: Jul. 12, 2007

(54) Automatic layer deposition process

(75) Inventors: Elke Erben, Dresden (DE); Stefan Jakschik, Leuven (BE); Alfred Kersch, Putzbrunn (DE); Angela Link, Munchen (DE); Jonas Sundqvist, Dresden (DE)

Correspondence Address: MORRISON & FOERSTER LLP, 1650 TYSONS BOULEVARD, SUITE 400, MCLEAN, VA, 22102, US

(73) Assignee: INFINEON TECHNOLOGIES AG, Munchen (DE)

(21) Appl. No.: 11/331,441

(22) Filed: Jan. 13, 2006

(30) Foreign Application Priority Data
Dec. 29, 2005 (DE) 10 2005 062917.2

(51) Int. Cl. H01L 21/8242

(52) U.S. Cl. 438/243

(57) ABSTRACT

The atomic layer deposition process according to the invention provides the following steps for the production of homogeneous layers on a substrate. The substrate is introduced into a reaction chamber. A first precursor is introduced into the reaction chamber, which first precursor reacts on the surface of the substrate to form an intermediate product. A second precursor is introduced into the reaction chamber, which second precursor has a low sticking coefficient and reacts with part of the intermediate product to form a first product. A third precursor is introduced into the reaction chamber, which third precursor has a high sticking coefficient and reacts with the remaining part of the intermediate product to form a second product. The second precursor and its first product reduce the effective sticking coefficient of the third precursor by partially covering the surface.

### CLAIM FOR PRIORITY

This application claims the benefit of priority to German Application No. 10 2005 062 917.2, filed in the German language on Dec. 29, 2005, the contents of which are hereby incorporated by reference.

### TECHNICAL FIELD OF THE INVENTION

The present invention relates to an atomic layer deposition process (ALD process) which is suitable for producing a homogeneous layer on a substrate.

### BACKGROUND OF THE INVENTION

For many applications, capacitors must not drop below a minimum capacitance. The capacitance of a capacitor is dependent, inter alia, on the surface area of the electrode surfaces of the capacitors. Therefore, their surface area must not drop below a minimum value.

There is a requirement for a large number of semiconductor components to be arranged at or on a surface of a semiconductor substrate. This is achieved by reducing the lateral dimensions of the semiconductor components and also of the capacitors. The minimum surface area of the electrode surfaces is ensured by virtue of the capacitor electrodes having a large vertical dimension.

With a generally known method for fabricating capacitors of this type, first of all a trench with a high aspect ratio is formed in the semiconductor substrate. A conductive layer which forms the first electrode is applied to the side walls of the trench. Then, a thin dielectric layer is deposited on the first electrode, forming the dielectric of the capacitor. Finally, the capacitor is filled with a conductive material which forms the second electrode.

High demands are imposed on the dielectric layer. On the one hand, it needs to be very thin, in order to achieve a high capacitor capacitance. On the other hand, it must not drop below a minimum thickness over its entire volume, since otherwise shortcircuits can form between the two electrodes at these locations. A suitable process for producing dielectric layers of this type is the atomic layer deposition (ALD) process. In this process, two different reaction gases, referred to as precursors, are alternately introduced into the trench. The precursors react substantially only with the reaction products of the other precursor, which cover the surface. On account of the self-limiting deposition of each individual precursor, the result is a monomolecular deposition of the product of the precursor on the surface. The thickness of the layer to be deposited is controlled in a targeted way by alternating introduction of the two precursors.

In trenches with a very high aspect ratio, only small quantities of the precursors with a low vapour pressure reach the base region of the trench. Complete coverage of the surfaces in the region of the trench is only achieved after an in some cases unacceptably long time following the introduction of the precursors. In particular precursors with a high sticking coefficient tend to react with the surface while they are still in the upper region of the trench, and consequently only very small quantities of these precursors reach the base region of the trench. The sticking coefficient is defined as the ratio of the number of chemisorption events on the surface to the number of contacts with the surface.

There is a requirement for the layers to be produced within an acceptable time. In this case, it is necessary to accept that the surfaces do not completely react with the precursors in the region of the trench base, on account of the small quantity thereof. This results in layer thicknesses of the dielectric which are lower in the region of the trench base than in the region of the trench opening.

### SUMMARY OF THE INVENTION

The present invention provides an atomic layer deposition process which can be used to produce homogeneous layers, in particular if one of the precursors has a high sticking coefficient.

The atomic layer deposition process according to one embodiment of the invention provides the following steps for producing homogeneous layers on a substrate. The substrate is introduced into a reaction chamber. A first precursor is introduced into the reaction chamber, which first precursor reacts on the surface of the substrate to form an intermediate product. A second precursor is introduced into the reaction chamber, which second precursor has a low sticking coefficient and reacts with part of the intermediate product to form a first product. A third precursor is introduced into the reaction chamber, which third precursor has a high sticking coefficient and reacts with the remaining part of the intermediate product to form a second product.

The sticking coefficient of the third precursor is influenced by the number of reaction sites which are covered exclusively by the first product.

The second precursor having the low sticking coefficient requires a greater number of contacts with the surface before it reacts with an intermediate product located on the surface. On account of the high number of attempts, the second precursor covers long distances before it reacts. This results in a relatively uniform distribution of the second precursor over the entire surface or of the product of the second precursor with the intermediate product on the surface. The third precursor reacts substantially only with the intermediate product and not with the first product, which results from the intermediate product and the second precursor. If the third precursor comes into contact with the first product, no reaction takes place. The high sticking coefficient of the third precursor is therefore reduced by the partial coverage of the surface with the first product. This results in a more uniform distribution of the third precursor over the surface and of its products with the intermediate product on the surface.

The first precursor and the two further precursors are introduced in succession. There is no time overlap between them in the reaction chamber. The precursors can if appropriate be pumped out for this purpose. The second and third precursors can also be introduced at the same time or with a time overlap.

According to another embodiment, the third precursor includes a metal compound or hafnium and/or zirconium and/or a lanthanide. The process is particularly suitable for metal compounds, since these generally have a high sticking coefficient of greater than 0.1. Precursors which transport hafnium, zirconium and the lanthanides also have a low vapour pressure, resulting in the risk of non-conformal layer deposition as a result of an insufficient quantity of precursor being introduced. In this case, the advantageous effect results from the reduction in the effective sticking coefficient by means of the second precursor. A suitable second precursor may be a silicon compound, e.g. silane. The first precursor may form hydroxyl groups by means of water vapour or ammonium groups by means of ammonia.

In another embodiment, the undesired first product is released from the surface following the introduction of the third precursor. The voids can be filled by monolayers that are subsequently applied. The releasing of the first product can be achieved by increasing the temperature.

In still another embodiment, the second precursor is released again from the surface following the introduction of the third precursor. The intermediate product which is formed can react again during the next introduction of the second precursor. The second precursor acts as an inhibitor.

### BRIEF DESCRIPTION OF THE DRAWINGS

The invention is described in more detail below with reference to exemplary embodiments and drawings, in which:

FIGS. 1-5 show part-sections through a semiconductor substrate on which a layer is deposited using an exemplary embodiment of the present invention.

FIG. 6 shows a part-section through a semiconductor substrate describing a second exemplary embodiment of the process according to the invention.

FIG. 7 shows a part-section through a trench capacitor which is fabricated using one of the exemplary embodiments.

In the figures, identical reference designations denote identical or functionally equivalent components.

### DETAILED DESCRIPTION OF THE INVENTION

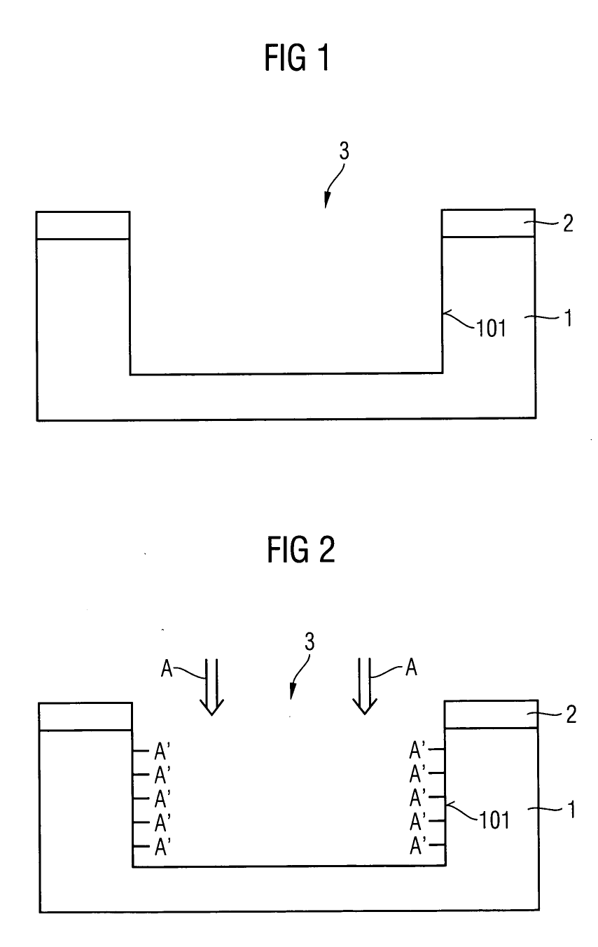

FIG. 1 illustrates a semiconductor substrate 1, for example made from silicon. A capping layer 2 of silicon oxide, silicon nitride or other passivating materials has been deposited thereon. A trench 3 has been formed through the capping layer 2 and into the substrate 1. Contrary to the geometry illustrated in FIG. 1, this trench may also have a very high aspect ratio, i.e. the depth of the trench is higher by a multiple than the width of the trench. In 90 nanometre technology, trenches with a depth of from 6 to 9 μm and an aspect ratio of 1:80 are typically produced. A thin layer with a thickness of just a few nanometres is to be deposited in the trench. In the text which follows, by way of example, the deposition of a thin layer of a dielectric material is described; however, it is also possible for metal layers with a high conductivity to be deposited in a similar way.

In a first step, a first reaction gas, referred to below as precursor A, is introduced into a reaction chamber. The precursor A is selected in such a manner that it reacts substantially with the substrate surface 101 and not with the capping layer 2 or with itself. The reaction of the precursor A with the substrate 1 produces an intermediate product A′ which accumulates on the surface 101 of the substrate 1, i.e. the precursor A is chemisorbed at the substrate surface 101. Contrary to the illustration presented in FIG. 2, the chemisorption may also take place in the region of the base.

A typical precursor A is water vapour which forms an intermediate product with hydroxyl groups (—OH) following the reaction with a silicon-containing substrate.

In a second step, a precursor B is introduced into the reaction chamber. This precursor B is selected in such a manner that it reacts substantially with the intermediate product A′, e.g. the hydroxyl groups, and not with itself. One possible precursor B is silane or another organic silicon-containing compound. Furthermore, the precursor B is selected in such a manner that it has a low sticking coefficient with respect to the surface 101 which is covered with the intermediate product A′. In other words, the probability of reaction between the precursor B and the intermediate product A′ must not be especially high. The sticking coefficient should typically be less than 0.01 (one reaction per 100 contacts of the precursor B with the surface). On account of the low sticking coefficient, the molecules of the precursor B cover relatively long distances, and therefore a substantially homogeneous distribution of the precursor B over the entire vertical surface of the trench is achieved. Accordingly, the product (AB′) of the precursor B with the intermediate product A′ is also distributed uniformly over the surface of the trench.

The quantity of precursor B which is introduced or its residence time in the chamber is set in such a manner that a part of the surface 101 reacts with the precursor B. Following this step, the coverage of the surface with the product (AB)′ should preferably be no greater than one fifth.

Then, the next precursor C is introduced into the reaction chamber. This precursor C, like the previous precursor B, is such that it substantially reacts with the intermediate product A′. In particular, the precursor C does not react with the product (AB)′ formed from the reaction of the precursor B with the intermediate product A′. A reaction takes place at the locations of the surface where previously no reaction took place between the intermediate product A′ and the precursor B. As a result, the sticking coefficient of the precursor C is effectively reduced and the mean distance covered by a molecule of the precursor C is increased. A greater number of molecules of the precursor C reaches the base region of the trench. Overall, therefore, a more uniform distribution of the precursor C and of its products (AC)′ with the intermediate product A′ over the entire surface of the trench is achieved.

Most metal-containing precursors have a high sticking coefficient (>0.1). Moreover, in the case of a hafnium-containing precursor (e.g. hafnium dimethylamide), a zirconium-containing precursor and/or a lanthanide-containing precursor, these precursors have a very low vapour pressure, and consequently there is a risk of an insufficient supply of precursor, so that the surface of the trench cannot be completely covered.

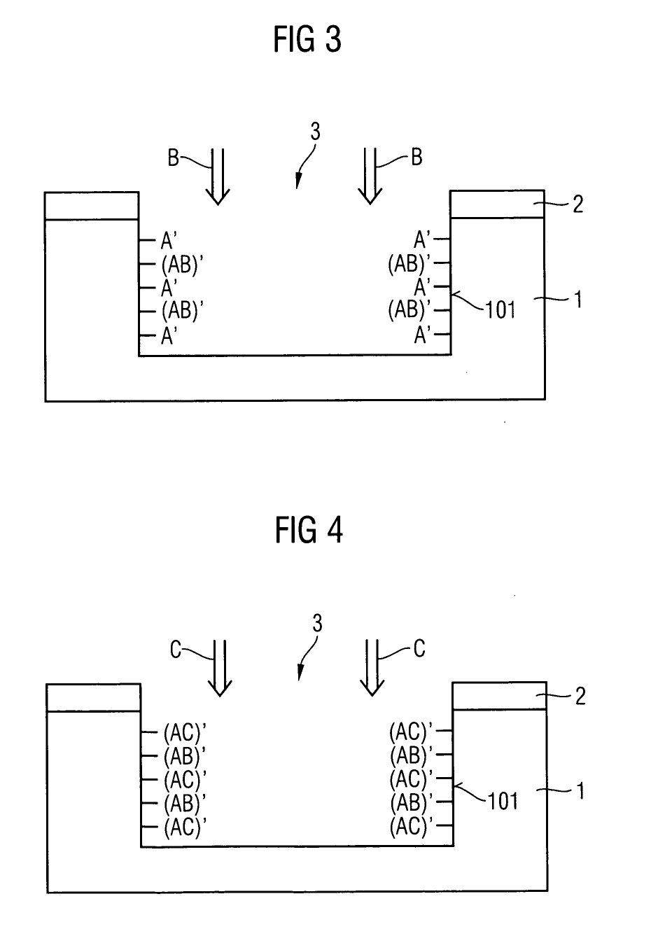

The process described in conjunction with FIGS. 2 to 4 led to the deposition of a single single-atom or monomolecular layer in the trench. To deposit the next layer, a further precursor, which may be identical to the first precursor A, is introduced into the reaction chamber. This precursor A reacts with the two products (AB)′ and (AC)′. This in turn produces the same intermediate product A′. Then, the steps which were described in conjunction with FIGS. 3 and 4 can be repeated. The number of repetitions determines the thickness of the layer which is deposited.

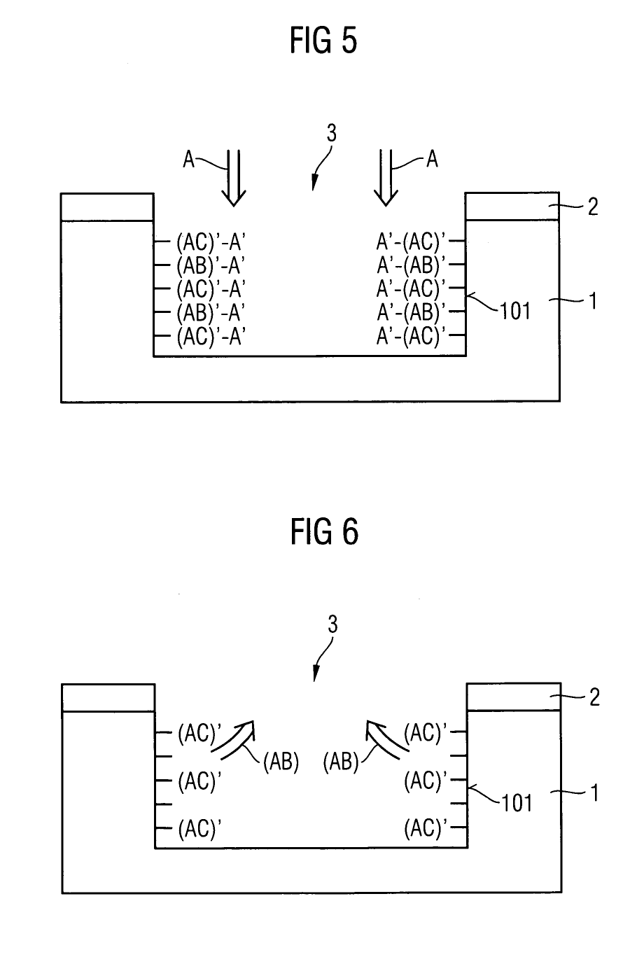

FIG. 6 illustrates a modification to the exemplary embodiment described above. In this case, the product (AB)′ is as far as possible released from the surface of the substrate 1 as a volatile gas (AB). This makes it possible to prevent the product (AB)′ from being included in the layer.

When forming layers that include hafnium nitride, for structural stabilization it is of interest to integrate the silicon atoms into the structure. Therefore, the use of a silicon-containing precursor B has proven particularly advantageous when producing the layer using the hafnium-containing precursor C. In this case, the silicon precursor advantageously reduces the sticking coefficient of the hafnium-containing precursor C and is at the same time incorporated in a homogeneous distribution into the crystal structure of the layer.

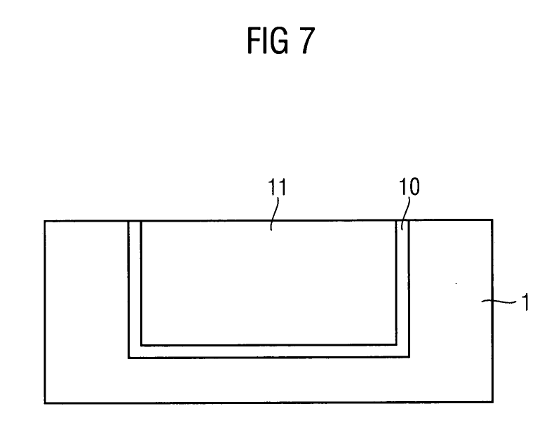

FIG. 7 shows a part-section through a trench capacitor having a conductive substrate 1, which forms the first electrode, a dielectric layer 10 and a filling of conductive polysilicon, which forms the second electrode. The dielectric layer can be produced by one of the above exemplary embodiments. In particular, it may predominantly comprise hafnium nitride and silicon. The proportion by mass of hafnium nitride is in a clear majority over the proportion by mass of silicon.

Although the present invention has been described in connection with the coating of trenches with a high aspect ratio, it is not restricted to this particular application. In particular, the process can also be used for large-area coating if a uniform flow of gas through the reaction chamber is not ensured.

### List Of Designations

1 Substrate
2 Capping layer
3 Trench
A, B, C Precursor
A′ Intermediate product
AB′, AC′ Product
AB Gas
10 Dielectric layer
11 Polysilicon

What is claimed is:

1. An atomic layer deposition process for producing homogeneous layers on a substrate, comprising:
introducing the substrate into a reaction chamber;
introducing a first precursor into the reaction chamber, which first precursor reacts on the surface of the substrate to form an intermediate product;
introducing the second precursor into the reaction chamber, which second precursor has a first sticking coefficient and reacts with part of the intermediate product to form a first product; and
introducing the third precursor into the reaction chamber, which third precursor has a second sticking coefficient, which is greater than the first sticking coefficient, and reacts with the remaining part of the intermediate product to form a second product.

2. The atomic layer deposition process according to claim 1, in which the third precursor includes a metal compound or hafnium and/or zirconium and/or a lanthanide.

3. The atomic layer deposition process according to claim 2, in which the second precursor includes a silicon compound or silane.

4. The atomic layer deposition process according to claim 1, in which the intermediate product includes a hydroxyl group and/or the first precursor includes water vapour.

5. The atomic layer deposition process according to claim 6, in which the volumetric ratio of the third precursor is to the second precursor introduced in a volumetric ratio of at most four to one.

6. The atomic layer deposition process according to claim 1, in which the first product is released from the surface following the introduction of the third precursor.

7. The atomic layer deposition process according to claim 1, in which the second precursor is released from the surface following the introduction of the third precursor.

8. A semiconductor component, which in a substrate has a trench with a high aspect ratio, the surface of which is covered with a homogeneous dielectric layer which contains a mixture of a metal nitride and a nonmetal.

9. The semiconductor component according to claim 8, in which the metal nitride includes hafnium nitride and/or zirconium nitride and/or a lanthanide nitride and/or the nonmetal is silicon.
